(19) United States
(12) Patent Application Publication
(10) Pub. No.: US 2011/0290173 A1
(43) Pub. Date: Dec. 1, 2011

(54) Methods and Systems for Characterization and Production of High Purity Polysilicon

(76) Inventors: David C. Spencer, Heath, TX (US); Jimmie D. Walter, Anna, TX (US); Friedrich H. Doerbeck, Dallas, TX (US)

(21) Appl. No.: 12/589,534

(22) Filed: Feb. 23, 2009

Related U.S. Application Data
(60) Provisional application No. 61/154,927, filed on Feb. 24, 2009.

(51) Int. Cl. C30B 15/30; C30B 15/16

(52) U.S. Cl. 117/28; 117/218

(57) ABSTRACT

Computer controlled quality control methods for manufacturing high purity polycrystalline granules are introduced. Polycrystalline silicon granules are sampled and converted into single crystal specimen in computer controlled system, eliminating the need of human operator in controlling the processing parameters. Single crystal silicon test samples, then characterized by FTIR and other standard analysis, are therefore more representative of the starting granular silicon.

### CROSS-REFERENCE

Priority is claimed from the U.S. provisional application No. 61/154,630, filed on Feb. 23, 2009 and the U.S. provisional Application No. 61/154,927, filed on Feb. 24, 2009, both which are hereby incorporated by reference in their entirety.

### TECHNICAL FIELD

This Application is directed, in general, to a process of silicon manufacturing and, more specifically, to a silicon micro-puller used for a conversion of polycrystalline silicon granules to monocrystaline silicon samples, as necessary for optical analysis.

BACKGROUND

Ultra-pure polysilicon is used in the semiconductor industry as the starting material for the growth of single crystals, from which then wafers are produced by grinding, slicing, lapping and polishing steps. Conductive polysilicon also finds applications as gate material for MOSFET and CMOS structures.

Before the large scale growth of single crystal Silicon ingots, the concentration levels of contaminants and dopants (such as Carbon, Boron, Phosphorus, Arsenic) in the polycrystalline starting material has to be known. Then the controlled addition of dopants to the silicon melt can be achieved.

Current standard practices for production control, quality assurance and material research is by Float-Zone Crystal Growth and Melter-Zoner Spectroscopies. See ASTM documents F 1708-96 “Standard Practice for Evaluation of Granular Polysilicon by Melter-Zoner Spectroscopies;” F 1723-96 “Standard Practice for Evaluation of Polycrystalline Silicon Rods by Float-Zone Crystal Growth and Spectroscopy;” F 1630-95 “Standard Test Method for Low Temperature FT-IR Analysis of Single Crystal Silicon for III-V impurities;” F 1389-92 “Standard Test Methods for Photoluminescence Analysis of Single Crystal Silicon for III-V impurities;” F 1391-93 “Standard Test Method for Substitutional Atomic Carbon Content of Silicon by Infrared Absorption.” The cited documents are contained e.g. in the 1998 Annual Book of ASTM Standards, Volume 10.05 Electronics (II). These documents are hereby incorporated by reference in their entirety.

The Document F 1723-96 “Standard Practice for Evaluation of Polycrystalline Silicon Rods by Float-Zone Crystal Growth and Spectroscopy,” applies to the treatment and test of polycrystalline silicon rods as produced by the Siemens Process. This process does not yield polycrystalline Si pebbles but large polycrystalline cylinders. Small diameter cylinders have to be cut and converted to single crystal by a process which is physically identical to the conversion of polysilicon pebbles. The applied test methods are then also identical.

The current standard quality control for manufacturing granular polysilicon uses the Float-Zone Crystal Growth method which takes place in a vertical quartz tube under flowing high purity argon. The silicon is inductively heated to the melting point using a microwave generator and an rf coil surrounding the quartz tube.

Briefly, samples of granular polysilicon pebbles are placed into the quartz tube of a Melter-Float Zone Apparatus in which the granular pebbles rest on a polytetrafluoroethylene (“PTFE”) plunger-diffuser. The tube is filled with polysilicon pebbles until the top of the pebble charge comes close to the lower part of the RF coil. A silicon pedestal is mounted on the upper chuck and centered within the quartz tube. The position of the whole carriage is manually adjusted so that the silicon pedestal extends into the rf coil.

Argon gas is first blown at higher flow rate through the PTFE plunger-diffuser to replace the oxygen in the quartz tube. The flow rate is later adjusted to a value just sufficient enough that only the top layer of granules is fluidized.

A hydrogen-air torch placed outside the quartz tube is ignited to heat the silicon pedestal to a temperature sufficiently high so that the electrical conductivity is raised until the silicon couples with the radio frequency (RF) field. An RF power coil is first turned to 80% of the operating power needed for melting silicon. Once the pedestal is observed to glow the torch is manually turned off and removed, and the RF power is manually increased until the bottom of the pedestal melts.

The PTFE plunger is manually moved until the fluidized silicon pebbles at the top of the pebble column touch the liquid end of the pedestal and go into solution. As the Si granules melt into the pedestal and the melt volume increases, the operator starts moving the entire carriage upward. The upper boundary of the liquid Si moves out of the working zone of the RF coil. Silicon crystallizes and forms the consolidated polysilicon rod.

The PTFE plunger-diffuser is then removed and a single crystal silicon seed (2.5×2.5×100 mm) (typically <100> oriented) is mounted in the lower chuck and the shaft is reinstalled. The lower shaft is manually moved upward until the seed crystal is about 5 mm below the tip of the consolidated polysilicon rod previously produced. The entire tube is purged with argon gas.

The hydrogen torch is manually ignited while the RF power is set at 80% of the power needed to melt silicon. When the bottom of the consolidated polysilicon rod begins to glow indicating RF coupling, the torch is turned off and removed. The RF power is increased until the bottom of the consolidated rod is molten. The single crystal silicon seed is then manually raised to penetrate into the melt and is held in this position until thermal equilibrium is established between the tip of the seed, the melt, and the bottom of the consolidated polysilicon rod.

Typically, an optimum RF power for the one-pass zone leveling process needs to be experimentally established. Next the motorized carriage movement is initiated. Moving the carriage downward, the liquid zone is moved upward and single crystal silicon growth is occurring.

The appearance of four growth facet lines for the case of <100>-oriented seeds indicate single crystalline growth.

When a sufficiently long Si single crystal has been grown, the lower chuck is manually moved downward to separate the grown single crystal from the melt.

After a visual inspection of the harvested single crystal silicon one or several 2 to 4 mm thick slices are cut from specified locations and submitted to low temperature FTIR analysis and other standard analyses.

Highest purity silicon has a background contamination level down to 1×10¹² per cubic centimeter, corresponding to an electrical conductivity of approximately 1 E4 ohm cm. In order to achieve full sensitivity of the available optical tests, such as low temperature FTIR, photoluminescence etc., required for these low concentration, the single crystal quality has to be as high as possible.

The prior art manually-operated process often produces insufficient control of the growth environment and growth conditions (gas pressure, gas flow rate, temperature, growth rate i.e. movements of the seed crystal and the polycrystalline source material). Moreover, stresses and defects in the single crystal render the optical low temperature tests less sensitive.

### SUMMARY

In one preferred embodiment, small samples of polycrystalline semiconductor granules are taken from the production stream and are tested in a computer controlled quality control system wherein the granules are first consolidated into a polycrystalline rod.

In another preferred embodiment, the consolidated polycrystalline semiconductor rod is further converted into a single crystal using a computer controlled micro-pulling machine.

In another preferred embodiment, the computer controlled consolidation process and the computer controlled micro-pulling are performed in the same machine in situ.

In another preferred embodiment the computer controlled consolidation process and the computer controlled micro-pulling process are performed in two separate machines in a coordinated fashion. The resulting single crystal samples are submitted to highly sensitive tests, e.g. FTIR, IR spectroscopy and others, for determination of contamination levels.

In another preferred embodiment, previously used processing parameters are stored in the computer of the micro-pulling system for later use and analysis. A touch screen may be used to display the status of the process parameters. Parameters may be changed either by direct input commands to the touch screen or through other user interfaces, such as internet connection, at remote terminals. Remote terminals may also be used for process monitoring.

### BRIEF DESCRIPTION

Reference is now made to the following descriptions taken in conjunction with the accompanying drawings, in which:

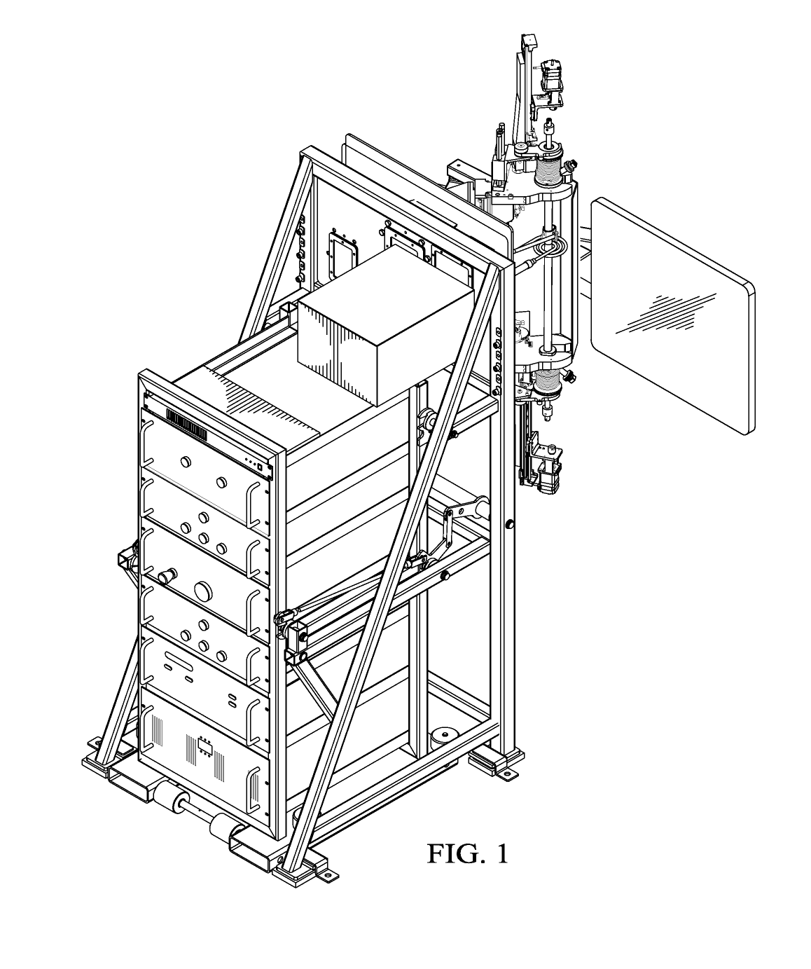

FIG. 1 presents a overview drawing of an example system in accordance with the present application.

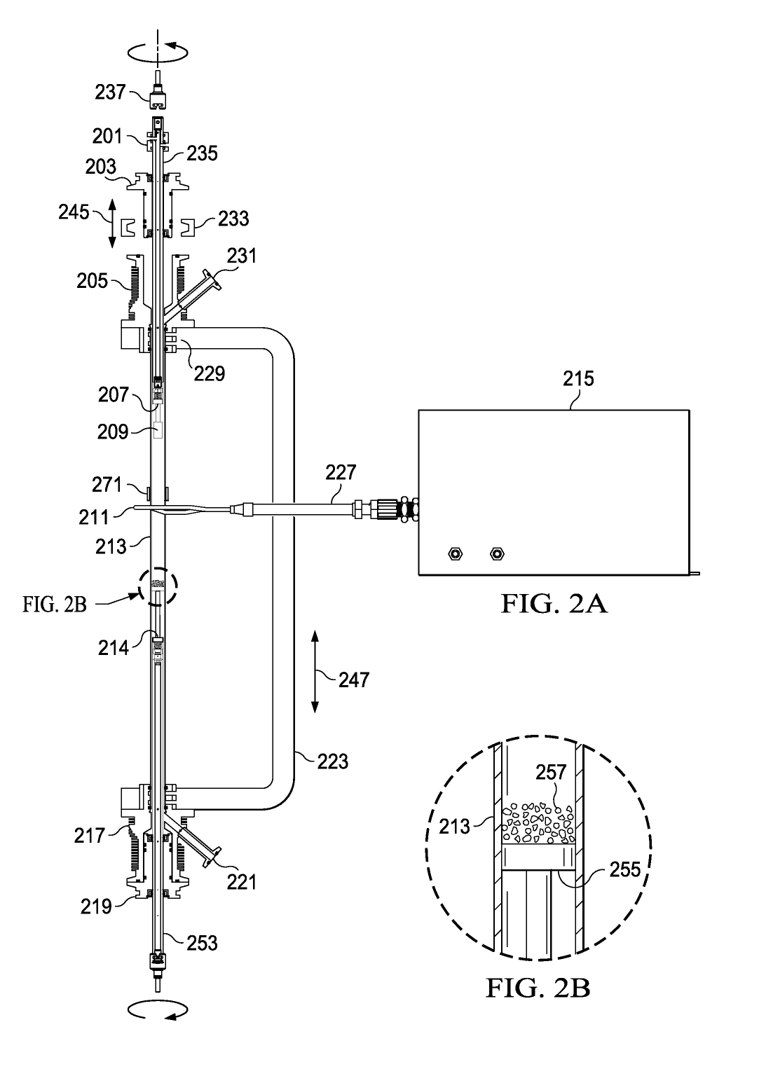

FIG. 2 shows a cross sectional drawing of the process quartz tube and attached components. The numbers refer to the List of Assigned Numbers which identifies these components by name. The insert FIG. 2B shows poly-silicon granules 257 supported by plunger 255, within the argon gas purged quartz tube 213.

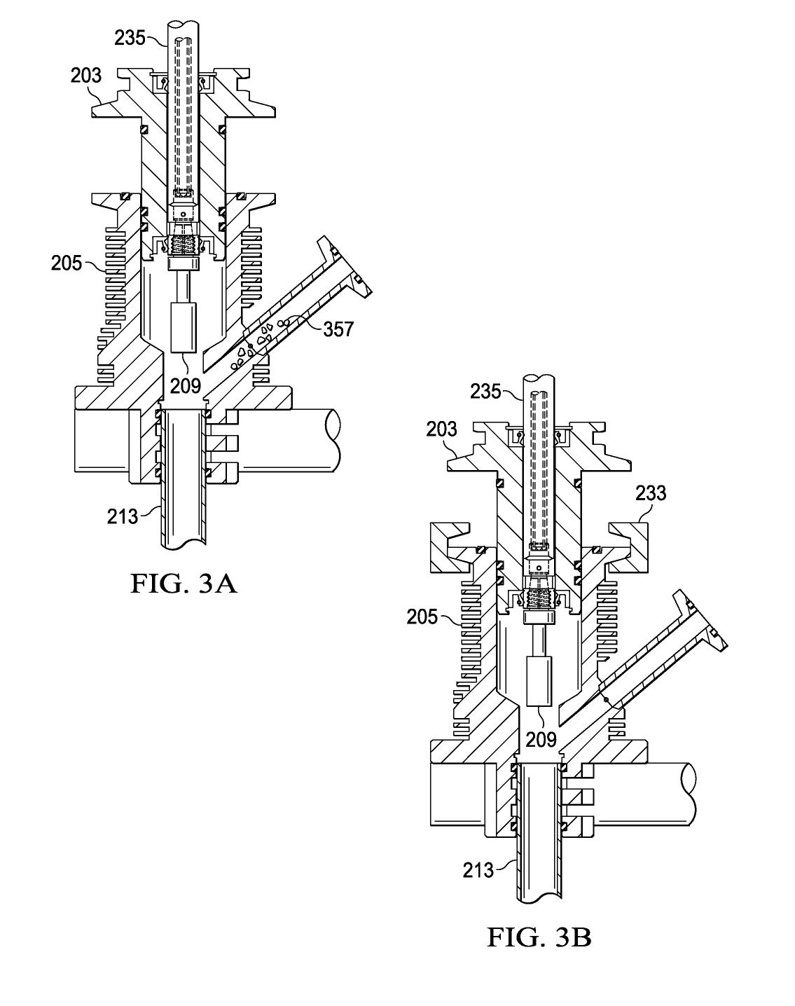

FIG. 3A shows a cross sectional view of details of the components at the upper end of the quartz process tube: the base mount, the shaft guide in elevated position, and associated seals etc. as an example system in accordance with the present application.

FIG. 3B shows a cross sectional view of the upper components, adding the clamp 233 shown in the applied position which is used when the shaft guide and the base mount are to be pressed together in accordance with the present application.

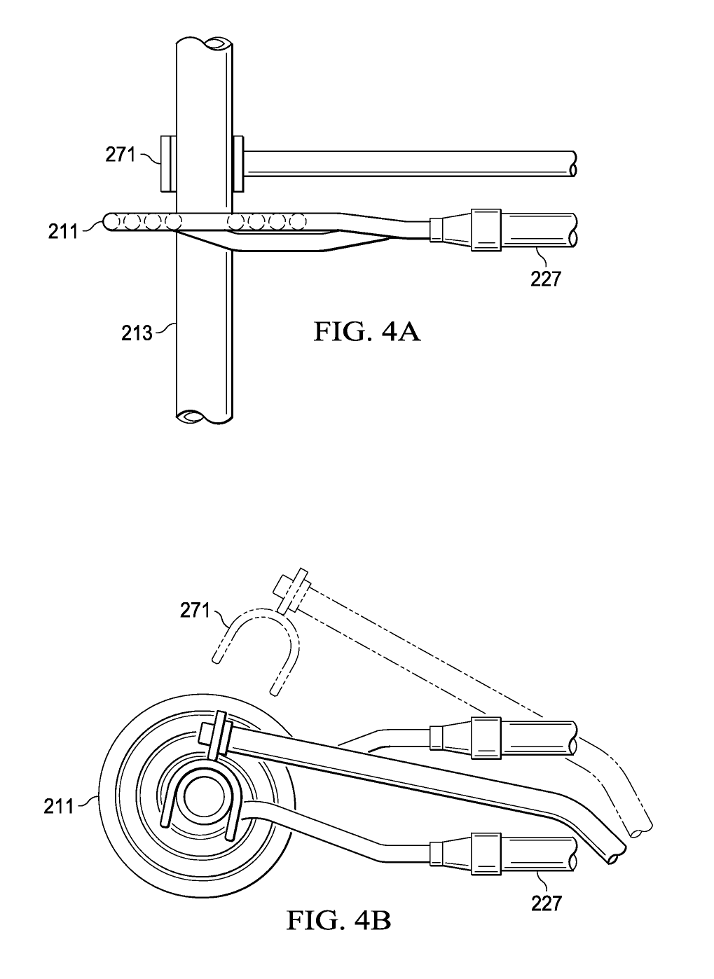

FIG. 4A and 4B show cross-sectional side and top views of an example process tube, encircled by the rf-heating coil 211 and with the susceptor 271 in engaged and disengaged positions in accordance with the present application.

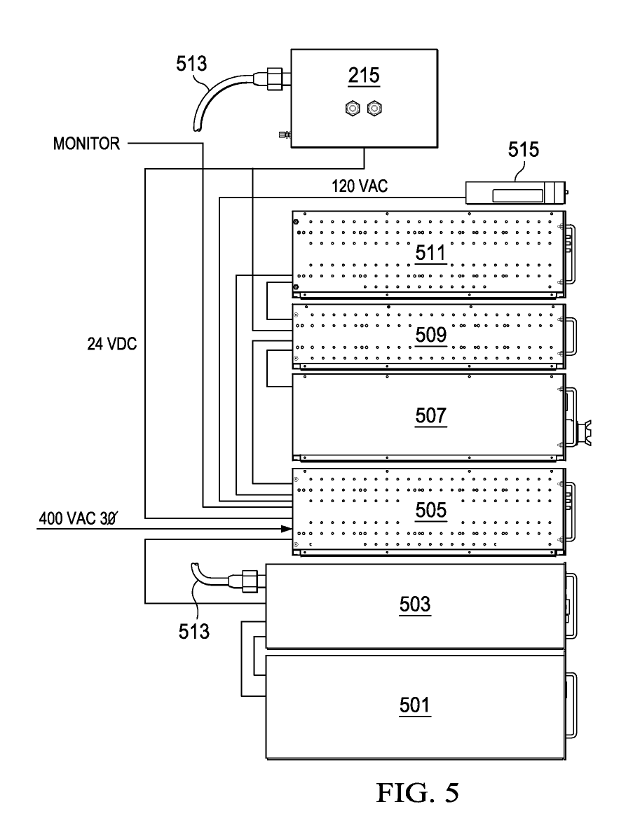

FIG. 5 shows a schematic view of an example of the organization of the various components used for the Process Control of the whole System, organized in 6 drawers, and the CPU 515 and the automated rf matching network 215, in accordance with the present application.

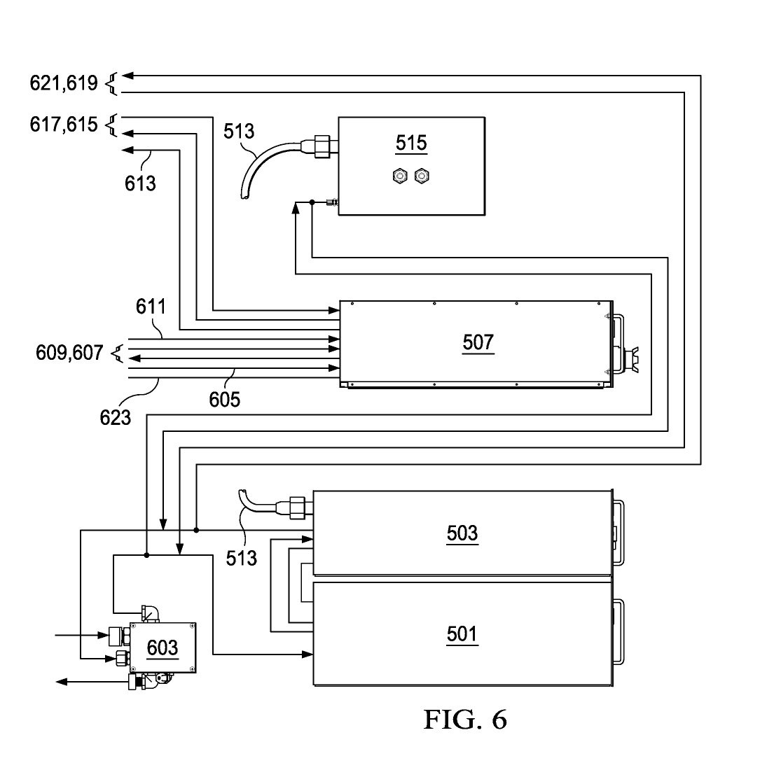

FIG. 6 shows a schematic view of an example Ambient Control, to control gas pressure, gas flow, fluid flow, with components placed in identified drawers, in accordance with the present application.

### DETAILED DESCRIPTION

Generally, the present application discloses new approaches to the quality control process for manufacturing high purity polycrystalline semiconductor granules, such as by using computer control, for a consolidation process as well as a micro-pulling process.

It is contemplated and intended that the system design applies to both single crystal growth from granular polysilicon pebbles and to single crystal growth from other polysilicon samples, for example, polysilicon samples cut from large polysilicon rods, for the process of quality control.

The disclosed innovations, in various embodiments, provide one or more of at least the following advantages. However, not all of these advantages result from every one of the innovations disclosed.
Improved precision of test results resulting in tighter process control
Higher reproducibility;
Faster turn around time.
Reduced learning curve for entry level operators.

These factors can contribute to yield improvements for the process of mass production of granular silicon.

Generally, when silicon is heated it reacts with water vapor or oxygen to form a surface layer of silicon dioxide. Pure silicon is a solid with the same crystalline structure as diamond. It has a melting point of 2570° F. (1410° C.). The high melting temperature provides a challenge for consolidating and converting polysilicon into single silicon crystal. The conversion process must be performed in an oxygen and water free environment and the temperature must be precisely controlled at all time.

The presented automated process and system for converting polysilicon material into a single silicon crystal, performed at a temperature of around 1410° C. in pure argon gas, provides the controlled environment with the needed consistency and control.

Turning to drawing FIG. 1, illustrated is a view of the micro-puller system in accordance with the present application. Generally, this micro-puller system is significantly smaller than prior art micro-pullers. Furthermore, most support components for the micro-puller system can be placed outside of a clean-room. Support has been assigned to two physical frames; one holding drawers containing power supplies, process control components, the RF generator 503, and in some embodiments, containing everything other than the reaction tube 213, such as a quartz tube, and any directly connected components, e.g. the base mounts 205 and 217 with shaft guides 203 and 219 etc. The inner frame can be rolled into the outer frame. The frames are connected together in a manner such that the weight is transferred to the outer frame near the floor, which leads to a low center of gravity for the outer frame with its attached process related hardware, thus offering maximum mechanical stability and resistance to vibrations. The outer frame also has provisions for mechanical anchoring to a solid floor.

FIG. 2 presents a schematic drawing, a side view of the part of the system where the process takes place.

The presented List Of Assigned Numerals defines names and functions of system and process components as used throughout the text.

List of Assigned Numerals:

| | |
|---|---|
| 201 | Cooling water seal |
| 203 | Upper shaft guide |
| 205 | Upper base mount |
| 207 | Upper chuck |
| 209 | Si pedestal |
| 211 | Rf coil |
| 213 | Quartz tube |
| 214 | Lower chuck |
| 215 | Automated rf tuning network |
| 217 | Lower base mount |
| 219 | Lower shaft guide |
| 221 | Lower gas port |
| 223 | Carriage |
| 227 | Rf-power connection |
| 229 | Cooling gas port |
| 231 | Upper gas port |
| 233 | Base mount clamp |
| 235 | Upper shaft |
| 237 | Bayonette coupling |
| 245 | Axis, shaft guide up/down |
| 247 | Axis, carriage up/down |
| 253 | Lower shaft |
| 255 | Plunger |
| 257 | Poly-Silicon granules |
| 271 | Susceptor |
| 501 | Rf power supply |
| 503 | Rf generator |
| 505 | System power supplies |
| 507 | Fluid, vacuum, gas control unit |
| 509 | Actuator drives, power supplies |
| 511 | Controller, I/O boards |
| 513 | Rf power cable |
| 515 | CPU |
| 603 | Flow control for cooling water |
| 605 | Air supply to drawer #507 |
| 619, 621 | Shaft cooling water |
| 615, 617 | Argon gas to quartz tube |
| 607, 609 | Argon gas to drawer #507 |
| 611, 613 | Cooling air for base mount |
| 623 | Vacuum to drawer #507 |

Also shown are lines for cooling water to drawers 501 and 503

The power and control system is schematically shown in FIG. 5. Organized in 6 drawers, it includes an RF power supply 501, an RF generator 503, a system power supply 505, a fluid vacuum and gas control unity 507, actuator drivers with power supplies 509, a controller and I/O cards 511, a CPU 501, a automated matching RF network 215, which transmits rf power from the microwave power generator 503, through cable 513 and the rf power connection 227 to the stationary rf coil 211.

The CPU 515 accepts programs and commands either remotely from a touch screen or a remote terminal. The remote terminal can operate the system in a similar manner as a local touch screen. The remote terminal can be employed via an Internet connection to the system, and can be operated by a remote operator.

After instructions are received by the CPU 515, they are converted into machine instructions. The machine instructions are communicated to the control unit 511 and to the RF power generator 503, which in turn is powered by the RF power supply 501. Inserted between the RF generator 503 and the RF coil 211 is the automated impedance matching network 215. It measures the reflected and the forward microwave power and automatically adjusts tuning components to minimize the reflected rf power.

Employment of the impedance matching network 215 leads improved rf-energy transfer, to better temperature stability and temperature control and thereby to improvements of the overall process control.

The controller unit 511 sends signals to the ambient control unit 507, which controls all gas/vacuum components (on/off valves, a mass flow controller etc.) and to the actuator unit 509, which controls various motions, such as all motions of the upper shaft 235, the lower shaft 253, and the carriage 223, all presented in FIG. 2, and to be discussed below.

In the controller system, the CPU 515 receives data from a feedback unit or from a human operator. One critical parameter is the size of the liquid silicon melt. This feedback, originating either from a device or a human, enables the system to precisely follow a pre-programmed process sequence for the consolidation of polycrystalline silicon granules into a polysilicon rod and then for its conversion into a mono-crystalline test sample.

Drawer 511 (controllers and I/O boards) also contains the rf power control unit, using connections to drawer 503 (rf generator) and to the Automated RF-Tuning Network 215. Data from radiation sensors can flow to drawer 511 (controller & I/O boards). Drives receive their commands from drawer 509 (actuator drives & power supplies).

The process takes place in a vertical quartz tube 213, under flowing high purity argon.

For processing polycrystalline Silicon granules, which have a typical, but not well defined, diameter of approx. 1 to 5 mm, the first step consists of a conversion into a polycrystalline silicon rod grown by this process onto a silicon pedestal 209.

For the consolidation of the silicon pebbles, a silicon rod, called pedestal 209, is used as base.

Extending from the upper shaft 235 the pedestal 209 is clamped into the chuck 207. Both shafts 235 and 253 can be raised, lowered and rotated, thereby moving the silicon pedestal 209, the plunger 255 or the mounted silicon seed.

After installing the upper shaft 235 with the pedestal 209, the upper shaft guide 203 and the shaft 235 are raised so that a path is cleared for loading Si pebbles through the upper port 231 into quartz tube 213, while not breaking the seal between base mount 205 and shaft guide 203. This design permits the loading of Si pebbles without removal of the upper shaft 235 from the system, while avoiding exposure of the Si pebbles to air.

Using a feeding insert, poly-Si granules 257 can be loaded through feeding port 231. The slopes of all tubes are selected so that the force of gravity is sufficient to let the Si pebbles slide/roll into tube 213.

The loaded Si pebbles rest on an inert plunger 255, made of inert material like PTFE, which is clamped into the chuck 214.

The pebbles form a column in quartz tube 213, e.g. 10 cm tall. High purity argon gas purges combined with vacuum cycles—controlled by Ambient Control Unit 507 connected to lower gas port 221—are first used to form an oxygen-free environment. Then the argon gas flow, precisely controlled by control unit 507, is adjusted so that the argon, after passing through a hole pattern in plunger 255, causes the Si pebbles to become fluidized, meaning that the pebbles at the top portion of the column become suspended in the flowing argon gas stream. Pebbles at the top of the column carry less weight than those at the bottom and are the first to be lifted up by the gas stream.

In one embodiment, purging efficiency can be enhanced by cycles of high and low pressure. “High pressure” can be generally defined as 2 atmospheres or higher, and “low pressure” can be generally defined as 1 milli-Torr and lower.

Both shafts 235 and 253, the tube 213, and all support components are attached to carriage frame 223 which can also be raised or lowered. The heater i.e. the RF coil 211 with turns encircling the quartz tube 213 is stationary. Raising and lowering carriage 223 moves the heating zone, which is the area with high radio frequency fields, close to the RF coil 211.

The process steps performed by this equipment are executed by coordinated movements of the shafts and the carriage, and by control of the RF power and the argon flow.

To render Si pedestal 209 sufficiently conductive for coupling into the RF field of the RF coil 211, pedestal 209 is positioned adjacent to RF coil 211 such that the bottom section of pedestal 209 is heated the most. Pedestal 209 is pre-heated by radiation from the RF heated susceptor 271. Once pedestal 209 is sufficiently hot and conductive and ready for further heating, susceptor 271 is moved sideways and out of the RF field, so that it does not interfere with subsequent process steps.

In one embodiment of the process, high purity argon gas enters through a lower gas port 221 and exits through an upper gas port 231. To prevent overheating of temperature sensitive parts, the base mount 205 has cooling ports 229 and internal cavities and passages for gas cooling of the base mount and of the end section of the quartz tube 213.

Both shafts 235 and 253 can be cooled by recirculating water and can rotate to equalize temperature non-uniformities, a common practice in the field of of crystal growth. FIG. 2 identifies the cooling water seal 201 for the upper shaft 235. Water cooling of the lower shaft 253 is presently considered not necessary for a process involving silicon.

The shafts are connected to their motors with bayonet-type quick-disconnects, identified as 237 in FIG. 2. Shaft guides 203 and 219 provide sealing and mechanical guidance during rotational and vertical movements of the shafts.

During removal of the shafts from the micro-puller for routine cleaning etc. shaft guide and shaft do not have to be taken apart. Handling of the shafts and the shaft guides as one unit, provides for easier and more precise assembly and disassembly.

Base mounts, shafts and shaft guides are interchangeable and can be used in the upper or equally the lower location.

In one embodiment, all metal surfaces that could come in contact with material in process are Teflon® coated, eliminating metal contamination.

In one embodiment, the controller system uses an Opto-22® Control System.

FIG. 3A and 3B illustrate a cross-section of paths which extend capabilities of this described system over previous designs. In FIG. 3A, the silicon pedestal 209 is clamped into the upper shaft 235, which can rotate and perform vertical movements, while keeping the contents of the quartz tube 213 isolated from a contaminating outside environment. The shaft guides 203 and 219 can be raised sufficiently to provide a clear path for loading spherical silicon pebbles 257 into the quartz tube 213 without requiring removal of the shaft 235.

FIG. 3B illustrates an upper clamp 233 which compresses the O-ring between the shaft guide 203 and the base mount 205, securing a tight seal.

FIGS. 4A and 4B show detailed views of both engaged and disengaged positions of the metal susceptor 271. In the engaged position the susceptor is heated by the rf-field, and then acts as radiative heat source for the silicon inside the quartz tube. FIG. 4B shows a top view with the susceptor 271 in the two positions.

Once the susceptor has accomplished the pre-heating, as evidenced by a beginning glow of the silicon, the susceptor swings into the disengaged position (FIG. 4A and 4B), the RF power is raised until the bottom section of the pedestal 209 turns liquid. Next the lower shaft 253 is raised and the argon gas flow adjusted so that the fluidized part of the Si-pebble column is moved into the proximity of the liquid part of the pedestal and dancing hot Si pebbles come in contact with the melt and go into solution. An upward motion of carriage 223 is then initiated, causing the liquid zone to move downwards. Gradually, more Si pebbles go into solution while simultaneously the top section of the melt leaves the hot zone, solidifies, and thereby forms the consolidated poly silicon extension to the silicon pedestal 209. Generally, employment of the susceptor 271 allows for an elimination of an open gas flame process, a significant safety improvement over prior art technology.

FIG. 5 presents a schematic of the Power Distribution, the Environmental Control, and of the physical layout of the total system, arranged in drawers. Beginning with the bottom drawer, the rf-power supply 501 is followed by the rf-generator 503, followed by System Power Supplies 505, followed by Ambient Controls (gas, fluid, vacuum) 507, followed by actuator drives and power supplies 509, followed by controller I/O boards 511, and the CPU 515. Also shown is the automated rf-matching network 215, and sections of the rf-power cable 513, which connects the rf-generator 503 with the matching network 215. The water cooled rf power connection 227 clamps directly into ports in the Tuning Network 215 and feeds rf energy to the water cooled rf coil 211.

FIG. 6 displays a preferred configuration for an ambient control system, which includes the Ambient Control unit 507, which contains components to control the gas flow rate and pressure in the quartz tube 213, plus the gas manifold (not illustrated) with on/off gas controls, which can include a gas pressure regulator and mass flow controller. The ambient control unit 507 also regulates cooling water flow and compressed air flow.

Cooling water is re-circulated from a cooling water supply (not illustrated) through the rf power supply 501, the rf generator 503, the automated tuning rf network 215, the rf coil, and the shafts 235 and 253, if so desired.

The control unit 507 receives argon through line 609 and emits argon to exhaust through line 607. The quartz tube 213 is connected to drawer 507 via lines 615 and 617.

The following part of the disclosure will be generally related to process.

Automated change between various positions of shaft guide 203 and 219 is achieved by a motor, such as a servo motor or a pneumatic motor. During the process, the shaft guide 203 is in the lowest position. All seals are in compressed state, ensuring a leak—and contamination—free environment. Pneumatic linear motors were selected for this function.

The next process step is for the polycrystalline extension to the silicon pedestal 209 to become converted to single crystal silicon.

The lower shaft 253 with shaft guide 219 and plunger 255 and the remaining, unconsumed, Si pebbles are taken out. Alternatively, the remaining, unconsolidated Si pebbles can also be removed through lower gas port 221. Using an unloading insert in port 221, the gravity driven round Si pebbles can be made to glide into a collection vessel.

Next a monocrystalline Si seed crystal of proper orientation is mounted on the chuck 214. The whole seed/chuck/shaft/shaft guide assembly is then re-installed into lower base mount 217.

The Si source material for the process of single silicon crystal conversion may also originate from silicon manufacturing processes that do not produce granules, but large bodies of polysilicon, such as the Siemens® process. For this machine the only requirement for a conversion from poly- to single crystal material is that the sample meets the geometrical specification. This can involve the use of maching tools.

After argon purge cycles, the seed, mounted on chuck 215, and the poly-silicon source mounted on chuck 207 is moved into position for preheating by the RF-heated susceptor 271. After coupling of the poly-crystalline source material to the RF field is achieved, susceptor 271 is moved to the disengaged position and the RF power is raised to melt the bottom of the Si polysource material.

The RF power, and the positions of both upper shaft 235 and lower shaft 253 with respect to the RF coil 211, are then selected so that the melted tip of silicon poly-silicon source is in the center of the RF coil 211, and is a few millimeters in length. When too thick, the melt will form a drop that causes damage when it disengages and falls down onto other components.

To begin the single crystal growth process, the lower shaft 253 is raised until the tip of single seed touches the hanging melt of the polysilicon source. The growth rate and the geometry of a growing single crystal are controlled by movements of the carriage 223 and of the shafts 235, 253.

Following techniques common for single crystal growth, a slight melt back of the seed is performed, and, after the establishment of thermal equilibrium, a neck is grown, followed by letting the crystal grow to the desired diameter, before body growth is initiated.

Precise control of all parameters i.e. the thermal environment and various movements, are critical for successful single crystal growth. Besides having tight control of the RF power generator 503 and automated matching network 215, this described system features rotating shafts, thus improving the uniformity of the thermal environment and providing means to influence the convection pattern in the liquid silicon.

After growing the desired crystal length, the growing crystal is separated from the melt, the system is cooled down. The crystal is harvested and several 2 to 4 mm thick slices are sawn off in specified locations for submission to precision tests, such as Fourier Transform Infra-Red (“FTIR.”) Misleading test results may be obtained when the test sample includes material from the Si pedestal or when too much seed material entered into the melt.

In the present application, to maintain the relationship between the impurity concentration of the starting granular silicon and the final test sample, purification by the system and by the process is normally undesirable. However, independent control of shaft movements (vertical and rotational) gives the operator a capability to minimize deleterious contributions, such as the addition of Si-seed material to the material under test.

Finally, a test sample is cut and prepared from the grown single crystal silicon, and submitted to tests, such as FTIR.

In one embodiment, the process steps of consolidation and single-crystal growth, taking advantage of aspects of the system, can be summarized as a series of steps, as follows:

### Consolidate Si Pebbles

1. Feed in Si pebbles.
2. Seal the system.
3. Argon purge the system with pressure/vacuum cycles.
4. Move shafts and carriage into position.
5. Position susceptor.
6. Do preheat.
7. Swing away susceptor.
8. Set Si-pedestal position and shaft movements.
9. Form liquid pedestal bottom (set RF-power).
10. Set argon flow to fluidize pebbles.
11. Run process using selected carriage and shaft movements.
12. Shut off process.
13. Remove bottom shaft assembly with plunger and remaining pebbles.

The process using the system continues with the Single Crystal Growth phase.
14. Mount shaft guide/shaft/seed assembly, and seal system.
15. Argon purge the system with pressure, which can include vacuum cycles;
16. Move shafts and carriage into position.
17. Select shaft movements.
18. Position susceptor.
19. Preheat bottom of poly-Si rod which was formed previously, using the RF-heated susceptor.
20. Swing away susceptor.
21. Melt bottom of poly-Si using the RF energy from the coil.
22. Do seed-dip by moving seed up.
23. Grow the single crystal making use of the adjustable parameters such as carriage movement, shaft movements, and temperature and gas controls.
24. Separate the single crystal from melt.
25. Unload the single crystal, prepare a test sample for e.g. Optical Tests.

### Considerations of Cycle Time

The steps requiring the longest period of time are the consolidation and single crystal growth because of the required achievement of thermal equilibrium and considerations of heat flow and heat of fusion. The time for the many short steps depend on the operator skill, and on the timely availability of prepared components.

Some additional discussion of important construction and engineering details of the system.

For use in a clean room environment, the system can be installed in such a manner, that only the parts directly associated with the quartz tube are on the clean side of a clean room wall. The areas of clean room wall penetrations are minimized.

Microwave power is supplied by a water cooled coil which surrounds the quartz tube, driven by a nominally 10 kW, 3 MHz solid state power source through an water cooled automated matching network. Automatically minimizing the reflected microwave power compensates for impedance changes due to silicon conductivity and melt size changes, and to changes of the load location with regard to the stationary rf-coil.

Safety improvements during the process of pre-heating of Silicon.

To raise the Silicon conductivity enough to achieve coupling to the rf-field, a horseshoe shaped metallic structure, called susceptor 271, is swung in, almost touching the quartz tube 213 and in very close proximity of the rf-coil 211. Radiation from this glowing metal is absorbed by the Si and the Si temperature rises. Once rf-coupling sets in, a positive feedback cycle takes over: rising temperature causes increased conductivity with increased rf-absorption and so on. The temperature rises very fast. An automated mechanism then removes the susceptor 271. Then the location of the Si is optimized for the next process step and the rf-power is adjusted to obtain the desired size of the molten silicon. The elimination of the use of an open flame for silicon pre-heating is considered to be a substantial safety improvement.

The basic principles of the system employ modern drive and control components. All motions of the carriage and the 2 shafts (vertical and rotational) are achieved by stepping motors or servo motors. The shafts are designed for water cooling. The chassis design stresses mechanical stability, resistance to vibrations, ease of access, maintenance and transportation. The stack of heavy drawers with power sources and control components rests on its own inner frame. The inner frame is rolled into the outer frame and the frames connect at floor level, providing a low center of gravity.

The outer frame, which holds all process related components, has provisions for bolting to the floor.

In one embodiment, the micro-puller system is controlled from a touchscreen, which is linked to the process computer. Parameters like rf-power, gas flow rate, gas valve status, rotations and movements of the shafts, the movement of the carriage, are controlled, monitored and can be adjusted any time. The whole process profile, including the adjustments, is temporarily stored in the computer. It can be permanently saved under a different name, and it is then available for future use and study. Program modifications and process monitoring and control can also be made via Internet.

The system offers water cooled shafts and shaft rotation. Shaft rotations provide for improved temperature uniformity and thereby better dimensional control of the growing crystal. The system offers the possibly to withdraw the shafts far enough out, without exposing the process volume to air, to present a clear path for pebble loading without removal of the upper shaft.

### Operator Safety Considerations

Generally, a quartz tube is the mechanically weak spot of the system. Micro cracks, possibly caused during the tube handling and installation, can cause failure under raised or lowered pressure. Operators need to be required to wear eye protection around the machine. Performance of pressure and leak rate tests should be considered after installation of a quartz tube.

The disclosed system and methods can be applied to work with a variety of other materials which require high temperature processing and/or crystal formation. Besides silicon these materials may include Ge, Group III-V Semiconductors as well as some organic crystal materials.

The system may be used for sample preparation from materials prepared by other techniques, such as crystal growth processes of Cz, LEC, and Bridgman, casting processes e.g. for ingots for solar cells, and for source material produced for thin film applications, such as vapor phase, liquid phase epitaxy, or evaporation, sputtering and plasma deposition, MBE and MOCVD processes, etc.

Those skilled in the art to which this application relates will appreciate that other and further additions, deletions, substitutions and modifications may be made to the described embodiments.

What is claimed is:

1. A system, comprising:
a process tube,
an upper mount coupled to the process tube,
a lower mount coupled to the process tube,
an upper shaft coupled to the upper mount that permits vertical and rotational movement of a clamped item, and
a lower shaft coupled to the lower mount that permits vertical and rotational movement of a clamped item.

2. The system of claim 1, wherein said process tube is a quartz tube.

3. The system of claim 1, wherein said upper and lower shaft can be water cooled.

4. The system of claim 1, further comprising an electrically conductive rf-heated susceptor whose radiation heats a selected material contained within the process tube.

5. The system of claim 4, wherein said electrically conductive susceptor is RF heated from an RF power generator, wherein the heated susceptor radiates heat and this heat is used to turn a non-conductive medium to a conductive medium.

6. The system of claim 1, wherein said upper shaft and said lower shaft have independent controls for rotation and vertical movement.

7. The system of claim 1, wherein said system is connect to and interfaces with the Internet.

8. The system of claim 1, wherein all metal surfaces which come in contact with process material(e.g. Si) are Teflon® coated.

9. The system of claim 1, wherein said upper base mount and said lower base mount are attached to a carriage that is moveable in a vertical direction.

10. The system of claim 1, applying methods for converting poly-crystalline materials to single-crystals, making use of:
a rotating lower shaft in a process tube that holds a inert plunger 255 to support poly-silicon granules or to hold a single-crystal seed;
a rotating, vertically moving lower shaft;
a rotating, vertically moving upper shaft holding a polysilicon rod.
Radiation pre-heating and rf-heating silicon material to the melting point to create a liquid zone in contact with different pieces of material.

11. The method of claim 10, wherein the timing for all of the above steps can be pre-set.

12. The method of claim 10, wherein an operator is not involved in running the method.

13. The method of claim 10, further comprising:
loading the process tube with silicon, including silicon granules; and
purging the process tube with at least one cycle of no higher than one hundred milliTorr and at least two atmospheres pressure of process gas.

14. The method of claim 13, wherein said process gas is Argon.

15. A system, comprising:
a process tube,
an upper mount coupled to the process tube,
a lower mount coupled to the process tube
an upper shaft coupled to the upper mount that controls vertical and rotational movement of a clamped item,
a lower shaft coupled to the lower mount that controls vertical and rotational movement of a clamped item; and
a controller that is coupled to:
a) said upper shaft and said lower shaft to control said vertical and rotational movements of said shafts; and
b) a carriage that is coupled to said upper mount and said lower mount and features motor driven vertical movements.

16. The system of claim 15, wherein said upper and lower shafts are designed for water cooling.

17. The system of claim 15, further comprising an electrically conductive susceptor that radiation heats a selected material contained within the process tube.

18. The system of claim 17, wherein said electrically conductive susceptor is RF heated from an RF power generator, wherein the susceptor radiates heat and the heat is used to turn a non-conductive medium to a conductive medium.

19. The system of claim 15, wherein said upper shaft and said lower shaft have independent controls of rotation and vertical movement.

20. The system of claim 15, wherein said system is coupled to the Internet.
